(19) United States
(12) Patent Application Publication
(10) Pub. No.: US 2007/0000407 A1
(43) Pub. Date: Jan. 4, 2007

(54) Nano composite photocatalytic coating

(75) Inventor: Man Loong Leong, Pahang (MY)

Correspondence Address: MCNEES, WALLACE & NURICK LLC, 100 PINE STREET, P.O. BOX 1166, HARRISBURG, PA, 17108-1166, US

(73) Assignee: York International Corporation, York, PA (US)

(21) Appl. No.: 10/557,011

(22) PCT Filed: Oct. 9, 2003
(86) PCT No.: PCT/US03/32110

§ 371 Date: Nov. 15, 2005

(51) Int. Cl. C04B 28/26; C23C 16/40; C09D 5/14; B05D 3/00; B05D 1/02; B05D 7/00

(52) U.S. Cl. 106/15.05; 106/287.19; 106/287.34; 427/299; 427/402; 427/421.1; 427/430.1; 427/240; 427/429; 427/180

(57) ABSTRACT

A photocatalytic coating composition and method of coating articles, the composition containing solvents for rapid evaporation at room temperature, polyalkylphenylsiloxane, xylene, nano densified hydrophilic fumed silica, nanostructured composite photocatalyst powder and nano inorganic anti-bacteria powder. The coating may be applied by conventional coating methods to organic or inorganic structured surfaces where photocatalytic activity is desired, such as in a forced air-circulating environment. Once applied, the coating quickly dries to leave an adherent, flexible, durable, and long-lasting photocatalytic coating having a large surface area and exhibiting high surface activity against pathogens and pollutants such as bacteria, viruses, mold, fungi, and volatile organic compounds.

### FIELD OF THE INVENTION

This invention relates generally to coatings and methods of coating. In particular, the invention relates to a novel nano composite photocatalytic coating used in heating, ventilation, air conditioning and refrigeration (HVACR) equipment, and to methods of applying the coating to such equipment. Once applied to a substrate, the coating is stable in ultraviolet, high-oxidation and high-temperature environments, such as in forced air-circulating systems containing ultraviolet light as a purification mechanism. The photocatalytic ingredients in the coating act as a catalyst when exposed to ultraviolet light to promote both photocatalytic oxidation of organic chemicals as well as the elimination of bacteria, viruses, dust mites, molds, spores, fungi and other pollutants by photocatalysis and biological enzymes.

### BACKGROUND OF THE INVENTION

Titanium dioxide is well known to act as catalyst in photocatalytic oxidation. When exposed to ultraviolet (UVA, UVB and UVC) light in a moist air environment, titanium dioxide photoreacts to generate free radicals. These free radicals react with nearby water molecules (H₂O) to form hydroxyl radicals (OH—). The hydroxyl radicals react with pollutants such as volatile organic compounds (VOC) to degrade the organic structure of the pollutants, thereby forming harmless carbon dioxide (CO₂) and water vapor. The free radicals and hydroxyl radicals also act to disrupt organic molecules in organic pollutants and pathogens such as bacteria, viruses, dust mites, molds, spores and fungi.

The use of titanium dioxide as a photocatalytic coating in fluid filters such as air and water purification systems has been described in several issued patents. For example, U.S. Pat. No. 6,093,676 issued Jul. 25, 2000 to Heller et al. sets forth a UV-illuminated catalyst that utilizes a photocatalyst and a binder to adhere to the substrate without heating. The photocatalyst is a transition metal oxide such as TiO₂ and the binder composition can be a silica or silicone such as polysiloxane. A co-catalyst such as silver or other Group 1B metals, Group VIA or VIIIA metals may also be included. However, no antibacterial powder is identified in the composition. Some manufacturers utilize a titanium oxide-coated metal filter as a catalyst positioned in an airstream in the presence of UVA light to reduce the concentration of pollutants in the airstream through photocatalytic oxidation.

Many photocatalytic coatings contain organic polymers that degrade when exposed to photocatalytic oxidation activity. In particular, the degradation of organic polymer film forming substances, as well as organic and inorganic pigments, in known coatings results in premature aging, pulverizing, cracking, shedding and delaminating of the coating. The highly oxidative nature of photocatalytic coatings also adversely affects their application on organic polymer substrates, since the substrate will be degraded by the photocatalytic properties of the coating.

Furthermore, many known photocatalytic coatings use granular ingredients which provide limited surface activity and limited life due to the surface area limitation created by the relatively large size of the particular ingredients. For the same reasons, known coatings exhibit poor oxidation resistance and heat resistance, low surface activity, poor adhesion and dispersion, skinning and poor coalescent properties, non-uniform thickness distribution, and slow curing. These rather large formulas are also difficult to work with, as they are hard to apply to any surface that is not flat and horizontal or substantially flat and horizontal. The mixtures tend to be runny and difficult to work with. If the composition is adjusted so that the mixture is thicker, the working time before the material cures is significantly shortened, making it difficult to apply to any but the most simple geometry. Known inorganic coatings capable of withstanding photocatalytic oxidation exhibit very limited working time before curing must commence. The properties of such coating solutions, including titania sol gel as further discussed herein, severely limit the application methods. Due to these limitations in working time and application methods, known coatings are not suitable for continuous use in production plants.

For example, titania (TiO₂) sol gel is widely used as a titanium dioxide-containing coating having photocatalytic oxidation properties. The sol gel process uses inorganic and metal organic precursors at low temperature to synthesize a coating product which is either totally inorganic, or a combination of inorganic and organic materials. The sol gel process is a multi-step process that involves appropriate organometallic compounds and alcohol-based mixtures and goes through hydrolysis and condensation reactions. One titania sol gel process utilizes titanium isopropoxide:ethanol:water:nitric acid in a mole ratio of 1:20:4:0.08. Two solutions are prepared and then mixed together: Solution A is formed by dissolving titanium isopropoxide in ethanol; Solution B is formed by adding water and nitric acid into ethanol. Then, Solution B is added to Solution A by mixing evenly. A transparent gel in homogenous gelation can be seen in a few minutes to several hours, depending on the temperature of the mixing. After application of the sol gel, curing by heat (such as an oven or heating tunnel) is required to produce a photocatalytic coating on the substrate.

Thus, there exists a continuing need for a photocatalytic coating that can be easily prepared and applied and which has a working time sufficiently long so that it can be used in a production environment for application to surfaces having complex geometries. The coating should be self-curing to avoid the need for expensive curing ovens or other type of curing equipment. Ideally, the coating should retain photocatalytic oxidation and antibacterial properties without degrading, particularly when used in HVAC systems such as a forced air-circulating system. Furthermore, there is a need for a primer coating that can be applied onto an organic substrate or other substrates to protect the substrate against undesirable oxidation by a subsequently applied photocatalytic coating of the present invention.

### SUMMARY OF THE INVENTION

The present invention is directed to a nano-composite substantially inorganic photocatalytic coating, comprising a substantially inorganic binder up to about 50%, a fumed silica, a nano-sized photocatalytic powder, an inorganic anti-bacterial powder having the general formula of YX(PO₄)₃ plus an antimicrobial metal, where Y is an element selected from Group IA and IIA of the Periodic table and X is an element selected from Group IIIA, IVA, VA and VIA of the periodic table and the balance is an evaporable carrier liquid. The amount of fumed silica, nano-sized photocatalytic powder and inorganic anti-bacterial powder is provided in an amount sufficient to provide thixotropic properties to the coating composition. The thixotropic properties are very important in allowing the coating to be applied in an industrial setting. Even though the coating dries quickly, its curing time can be 12 hours or longer. The thixotropic nature of the coating allows it to be applied to a surface by a variety of processes without running, slumping or sagging while it dries, and allows the coating to be worked as necessary while curing. As used herein, the term thixotropic refers to a property of a material composition that enables it to flow when subjected to a mechanical force such as a shear stress or when agitated and return to a gel-like form when the mechanical force is removed. This definition is consistent with the definition of thixotropy as set forth in Hawley's Condensed Chemical Dictionary (Thirteenth Edition) and the Encyclopedia Britannica. This property allows the coating to be applied in a production or industrial setting to surfaces having complex geometries, including but not limited to tubes, while assuring complete coverage without exposing the tube as a result of slumping, running or dripping of the coating.

The coating of the present invention acts as a catalyst in the presence of ultraviolet (UV) light. The ultraviolet spectrum is broken into several bands. UVA encompasses wavelengths in the range of 320-400 nanometers (nm). UVB encompasses wavelengths in the range of 290-320 nanometers. UVC encompasses wavelengths in the range of 200-290 nanometers. The catalytic effect of the coating is dependent upon the band of ultraviolet light that is present, as different bands produce different effects. When exposed to UV, the coating is a catalyst in photocatalytic oxidation and, in the presence of water molecules, ionizes the water to form hydroxyl (OH—) radicals that oxidize organic molecules. The hydroxyl radicals also disrupt the activities of airborne pathogens such as viruses, bacteria, dust mites, mold spores and fungi. Of course, UVC also is used to destroy bacteria and viruses. The present invention envisions using the coating on HVACR equipment in the presence of both UVA and UVC to take advantage of the photocatalytic oxidation of the coating and the ability of UVC to further destroy bacteria and viruses.

In a broad embodiment, the coating has a composition, in weight percent, of an effective amount of substantially inorganic binder up to about 50%; about 0.5-5% fumed silica; about 1% to about 10% nano-sized photocatalytic powder; about 1% to about 10% inorganic anti-bacterial powder that includes an inorganic anti-bacterial powder of YX(PO₄)₃ and at least about 3% of an antimicrobial metal, where Y is an element selected from Group IA and IIA of the Periodic table and X is an element selected from Group IIIA, IVA and VA of the periodic table and the balance an evaporable carrier liquid. This composition of the coating by weight, after removal of the evaporable carrier liquid, includes up to about 65% binder, about 7-14% fumed silica, about 13-28% nanosized antibacterial powder and the balance, typically about 13-28%, photocatalytic powder. While the amount of fumed silica, nano-sized photocatalytic powder and inorganic anti-bacterial powder is provided in an amount sufficient to provide thixotropic properties to the coating composition, a composition that provides an amount of photocatalyst powder that is no more than 15% of the binder, an amount of antibacterial powder that is no more than 15% of the binder, an amount of hydrophilic fumed silica that is no more than 5% of the binder and the balance xylene is also a broad composition that is effective. Thus the composition is no more than about 11% antibacterial powder, no more than about 11% photocatalyst powder, no more than about 3.7% fumed silica and the balance binder.

The method for applying the nano-composite substantially inorganic photocatalytic coating of the present invention includes the steps of providing quantities of the above-listed ingredients in the amounts required. After the ingredients are provided, the nano-sized photocatalytic powder is added to the carrier liquid and mixed to substantially uniformly distribute the powder in the carrier liquid. The inorganic anti-bacterial powder is also added to the carrier liquid and mixed to substantially uniformly distribute the inorganic powder in the carrier liquid. After the carrier liquid and the anti-bacterial powder are added to and mixed with the liquid, the fumed silica is then added to the mixture and mixing to substantially uniformly distribute the fumed silica in the mixture. After the fumed silica is distributed in the mixture the inorganic binder is added to the evaporable carrier and mixed to substantially uniformly distribute the binder in the carrier.

The fumed silica, nano-sized photocatalytic powder and inorganic anti-bacterial powder, also provided in a nano-size, in the evaporable carrier provide thixotropic properties to the coating mixture. The quantity of evaporable carrier liquid is then adjusted to provide the mixture with a viscosity suitable for application of the thixotropic mixture to a surface. The viscosity can be adjusted for different applications. Although the coating is gel-like after application, when subjected to mechanical forces, it will flow, and the viscosity will vary depending upon the amount of evaporable carrier liquid present. It will be understood that the fluidity/viscosity of a composition applied to the article will depend upon the method by which it is applied, as the coating will utilize a different fluidity/viscosity depending upon whether the coating is applied by dipping, spraying, brushing, etc.

In addition to the obvious advantages of the coating and its ability to act as a catalyst when exposed to UV radiation for photocatalytic oxidation of organic compounds, the present invention also enzymatically attacks micro-organisms such as bacteria and viruses. In addition, the composition of the present invention provides a number of other advantages not found in prior art compositions.

An advantage of the present invention is that it includes no polymeric film that can decompose. As a result, the film has better resistance to aging, as it will not readily deteriorate by pulverizing, cracking, shredding or delaminating.

Another advantage of the present invention is that it quickly dries in air, and self-cures, in air as a result of the evaporation of the solvent and without the need for a catalyst. As a result, no expensive heat curing furnaces or light curing equipment is required. Also, there is no need to monitor and protect the atmosphere for emissions from the curing composition, other than the emissions resulting from the evaporation of the solvent.

Another advantage of the present invention is the thixotropic nature of the composition. This allows the coating to better adhere to a substrate, even when the substrate has a complex geometry. The thixotropic nature of the composition combined with the self-curing in air provides the coating mixture with a longer working time, thus making the coating suitable for production processes, such as application to HVACR equipment.

Yet another advantage of the present invention is that it is applied as a very thin coating, so that it adds very little weight to the structure to which it is applied. On curing, it forms a dense oxide protective scale. And although the coating is applied in very thin layers, the oxide scale provides the cured coating with low oxygen diffusivity.

The present invention provides a fast drying, durable, adherent and flexible nano composite coating that exhibits photocatalytic properties and superior anti-microbial properties, and which retains desirable coating properties in hostile environments such as heat, photocatalytic oxidation, and ultraviolet light environments. The coating is easy to apply by any of a wide variety of coating apparatus and techniques, and is self-curing with no need to apply heat, microwaves, plasma, or infrared rays for curing.

The present invention further provides a primer coating that is suitable for use particularly on an organic substrate, although it may be used on any other substrate, to protect against undesirable oxidation by a subsequently applied photocatalytic coating.

The advantages the present coatings compared to known coatings include easy and fast production using commercially available mixing apparatus, application by a wide variety of coating techniques, and self-curing at room temperature. Thus, the coatings of the present invention are more suitable and economical for mass-production applications such as in manufacturing and assembly factories for air handling equipment.

Other features and advantages of the present invention will be apparent from the following more detailed description of the preferred embodiment, which illustrates, by way of example, the principles of the invention.

### DETAILED DESCRIPTION OF THE PREFERRED EMBODIMENTS

The present invention provides fast drying composite photocatalytic coatings, that are resistant to ultraviolet, oxidation and high temperature environments. The photocatalytic coatings, when exposed to UV acts as a catalyst for photocatalytic oxidation resulting in deodorizing, cleaning, and sterilizing of fluids such as air, gas, and liquids, as well as for disrupting the life cycle of micro organisms. When additionally used with UVC, the destruction of micro-organisms is further enhanced. The present invention further contemplates the use of a primer under the coating, particularly for use on organic surfaces to which the coating may not adequately bond. This invention can be used in HVACR systems for air conditioners, dehumidifiers, refrigerators, heaters, coolers, air purifiers, deodorizers, ventilation fans and germicidal equipment. However, the invention is not restricted to HVACR applications and other applications in building and construction industries include use on the surface of concrete, caulk, gypsum, tiles, roofing, ceramic tiles, cultured stones, paints, ceilings, timbers, plastics, blinders, signage, furniture and grills. The coated substrates and products when exposed to sunlight or ultraviolet light will deodorize, clean, repel micro-organisms, and sterilize organic compounds and stains.

The photocatalytic coating composition contains at least one photocatalytic ingredient, an inorganic binder, an inorganic anti-bacterial powder, and at least one organic solvent. Additional ingredients, such as thickening and anti-sagging agents, also are included to impart special properties to the coating enabling it to be used in an industrial manufacturing setting.

In a preferred formulation, at least one photocatalytic ingredient is a nanostructured composite photo catalyst powder containing a transition metal or its oxide as the active photocatalytic agent. Preferably, titanium dioxide, TiO₂, is provided as the photocatalytic powder, preferably in a nanosize, about 75 nm or smaller. In this formulation, the preferred anti-bacterial ingredient is a nano-structured powder of sodium (Na) a species of zirconium and a phosphate or phosphate salt that additionally includes at least about 3% (by weight) of silver. One anti-bacterial ingredient is NaZr₂(PO₄)₃ that includes at least about 3% silver. A preferred anti-bacterial powder is CYK-302 available from Chengyin Technology Co. Ltd. Of Shenzhen, China and includes by weight about 4.3% Na₂O, about 43.9% P₂O₅, about 0.02% NiO, about 1% HfO₂ about 3.8% Ag, and the balance ZrO₂ and incidental impurities. The inorganic binder is preferably polyalkylphenylsiloxane, and the organic solvent is preferably xylene. Densified hydrophilic fumed silica is provided as the anti-settling, thickening and anti-sagging agent. Preferably, all ingredients are provided as nano-sized particles.

For the purposes of this application, the following definitions apply:

Nanostructured composite photocatalyst powder—(hereinafter referred to as “NCPP”) is an ultra fine white powder, with an average particle diameter of 30 to 50 nano meters. NCPP contains an active ingredient containing a photocatalytic agent such as anatase titanium dioxide or another transition metal or its oxide, the active ingredient having a content of valid composition of equal or more than 80 percent. Other suitable transition metals include zirconium, molybdenum, niobium, hafnium, tantalum and oxides of these metals. NCPP has a hydrophilic surface property that exhibits high surface activity when dry, and good dispersion properties in solution. The nanostructure composite character of the NCPP yields a high level of photocatalytic activity and a long lifespan. When wastewater or polluted air passes its surface, organic pollutants are degraded by photocatalysis—thus it is self-cleaning and sterilizing. The preferred NCPP is commercially available from Chengyin Technology Co., Ltd. under the trade names “CYC-1” and “CYC-2” and have the following properties:

| | | | TiO₂ | | |
|---|---|---|---|---|---|
| | | TiO₂ | crystal | | |
| Item | Appearance | content | type | Diameter (nm) | Purpose |
| CYC-1 | White or light | ≧80 | Titanium | 30-50 | Purification of sewer |
| | yellow | | | | and exhaust gas, self- |
| | | | | | cleaning paint and air |
| | | | | | purification |
| CYC-2 | White or light | ≧80 | Titanium | 30-50 | Anti-bacteria material |
| | yellow | | | | |

Polyalkylphenylsiloxane—An inorganic substance in which the main chain contains no carbon atoms that is added as a binder. Behavior similar to that of an organic polymer can be developed, i.e., covalent bonding and cross-inking. It can be used as an intermediate for organic resin modification to improve oxidation resistance, thermal resistance, weather resistance, water resistance, gloss and electric properties. It is compatible with various organic resins such as alkyd, acrylic, epoxy, phenolic, polyester, polystyrene and silicone. It can be used for cold blending and modification. The appearance of polyalkylphenylsiloxane is yellowish transparent with the specific gravity of 1.07 at 25° C.; viscosity of 20 cP at 25° C.; 60% solid content; one hour curing time at 150° C.; functional group of —OH (4-5%); and can be diluted in solvent. An exemplary polyphenylalkylsiloxane is commercially available from GE Toshiba Silicones Co., Ltd. under the trade name “TSR160.”

Inorganic anti bacteria powder—Inorganic anti bacteria powder (hereinafter referred to as “IABP”) is a white powder compounded from ultra fine inorganic materials. The powder has an average diameter of 500 nm and large surface area with high stability in terms of chemical and heat properties. The IABP contains an active ingredient having a photocatalytic agent of the formula YX(PO₄)₃, and a noble metal where Y is at least one metal selected from Group IA and IIA of the Periodic Table. Y may include Na, K, Ca and Mg. X is an element selected from Group IIIA, IVA and VA of the periodic table, and may include titanium, zirconium, yttrium, hafnium, tantalum, tungsten, molybdenum and oxides thereof. The noble metal may include silver, gold, platinum, palladium, rhodium, combinations thereof and oxides thereof. One preferred antimicrobial agent includes NaZr₂(PO₄)₃, and at least about 3% by weight silver or its oxides. The antimicrobial metal content is preferably more than about 3% of the total IABP by weight. The active ingredient, silver may account for as much as 99% of the IABP on a weight basis. A preferred IABP is commercially available from Chengyin Technology Co., Ltd. under the trade name “CYK-302” having a composition, in weight percent, of about 4.3% Na₂O, about 43.9% P₂O₅, about 0.02% NiO, about 3.8% Ag, about 1% HfO₂ and the balance ZrO₂ and incidental impurities and has the following properties:

| | |
|---|---|
| Product Name | CYK-302 |
| Appearance | White powder |
| Silver content (%) | ≧3.0 |
| Primary particle size (μm) | ≦0.5 |
| Density g/cm³ | 3.6 ± 0.3 |
| Ratio surface area > m²/g | ≧25 |
| Temperature limit (C.) | ≧800 |
| PH | 1˜10 |
| Rate of antimicrobial (% 0.5% | ≧99 (anti-escherichia coli) |
| solution) | |

The manufacturer indicates that CYK-302 has an anti-bacteria rate of more than 99%, tested on Escherichia Coli, and is effective in a broad-spectrum manner as a result of its photocatalytic activity. Due to its small diameter and even scattering, the powder can be added without adversely affecting the properties of other powders and mixtures. CYK-302 can thus be applied in a wide variety of applications to impart anti-bacterial, anti-mildew, and anti-odor properties.

Solvent. An evaporable carrier liquid (“solvent”) is added to provide for proper mixing of the components and for proper application of the coating to the surfaces of the components. The solvent content can be adjusted to modify drying time and to provide an acceptable fluidity for application. For example, the coating of the present invention can be applied by brushing, spraying, dipping and rolling. However, the fluidity/viscosity of the composition can be adjusted depending upon the methods of application. To achieve the proper fluidity, the amount of solvent is increased. The solvent content is similarly adjusted to provide adequate fluidity/viscosity for other application methods. It will be understood by those skilled in the art that as the solvent content increases the drying time for the coating also increases. Suitable solvents particularly useful with polyalkylphenylsiloxane include toluene, alcohol, methyl ethyl ketone, and propylene glycol monomethyl ether acetate. Of the several available alcohols, isopropyl alcohol is preferred. Any other solvent that is compatible with polyalkylphenylsiloxane and the other ingredients may be used, with environmentally friendly solvents preferred. One preferred solvent is xylene (dimethylbenzene, C₆H₄(CH₃)₂)—which is made of three isomers, ortho-, meta-, and paraxylene. It is a clear liquid; soluble in alcohol and ether; insoluble in water; having a specific gravity of approximately 0.86; and a flash point from 81 to 115° F. (TOC). It is easily available commercially and mainly use in aviation gasoline, protective coatings, solvent for alkyd resins, lacquers, enamels, rubber cements, and synthesis of organic chemicals.

Densified hydrophilic fumed silica—A colloidal form of silica made by combustion of silicon tetrachloride in hydrogen-oxygen furnaces. The appearance of fumed silica is as fine white powder, preferably with an average primary particle size of about 12 nm and tap density of approximately 120 g/l. The loss on drying based on 2 hours at 105° C. is about 1.5% and the ignition loss based on 2 hours at 1000° C. dried material for 2 hours at 105° C. is about 1%. Its pH in 4% dispersion is about 3.7 to 4.7. It has more than 99.8% of SiO₂ content based on ignited material. Densified hydrophilic fumed silica is used as a thixotropy control of liquid system, binders and polymers; as anti-settling agent, thickening and anti-sagging agent; reinforcement of HCR-silicone rubber; improvement of free flow and anti-caking characteristics of powders; reduced dust development; and improved incorporation and handling due to a homogeneous and gentle densification. An exemplary densified hydrophilic fumed silica is commercially available from Degussa AG under the trade name “Aerosil 200 VV 120.” The fumed silica imparts the important thixotropic properties to the coating of the present invention, allowing it to be applied by any of a number of processes successfully in industrial applications. These important thixotropic properties allow the coating to be applied to a surface by any one of a number of processes such as spraying, dipping, brushing etc. The applied coating will not flow such as by slumping, running, or dripping after application due to the effects of gravity. However, the coating will flow if it is subjected to a mechanical shear stress, allowing it to be worked, if so desired. Thus, during the drying period the coating can be worked. Of course, the ability to work the coating will be gradually diminished during the curing period, which is dependent on the curing of the binder, up until curing is complete. These properties allow the coating to be used in high volume industrial applications and overcome problems of dripping and running experienced with other coatings, which leave portions of the substrate uncoated.

The photocatalytic coating solution is easy to apply using conventional coating apparatus, since it is provided as a mixture of ingredients suspended in an organic solvent. The preferred embodiment of the coating formulation is provided as a mixture of NCPP, polyalkylphenylsiloxane; IABP, and nano densified hydrophilic famed silica, all suspended in a fast-drying organic solvent. In the preferred formulation, the NCPP includes TiO₂ as the photocatalytic agent to promote catalytic oxidation to degrade volatile organic compounds into carbon dioxide and water. Polyalkylphenylsiloxane serves as the inorganic binder, IABP provides additional photocatalytic properties, as well as antibacterial properties and natural anti-microbial properties of noble metals such as silver and silver oxides. Xylene is the preferred organic solvent and has been shown to provide excellent dispersion characteristics, as well as fast drying to yield a self-curing coating at ambient room temperature. Densified hydrophilic fumed silica provides additional favorable coating characteristics, as discussed above, such as anti-settling, thickening and anti-sagging so that the coating can be applied to yield a uniformly thick, flexible, and adherent film on plastics, metals, and other complex geometric surfaces.

The photocatalytic coating can be applied to an organic or inorganic surface, and is self-curing, requiring no post-deposition catalyst reaction or other post-application treatment curing treatment (such as a gas or combustion related treatment or electrical furnace, microwave, plasma, light or infrared ray treatment). Upon application and curing, the coating exhibits excellent long-acting oxidation protection of the underlying substrate, as well as excellent resistance to moisture and other environmental conditions which can commence within about 15 minutes of coating, depending upon the amount of solvent used for the application. Furthermore, the photocatalytic agent in the coating acts as a catalyst when exposed to UV by promoting photocatalytic oxidation to convert organic pollutants into harmless carbon dioxide and water vapor, and further creating free radicals that disrupt the life cycle of airborne pathogens such as bacteria, viruses, dust mites, molds, spores and fungi.

The use of nano-size particles provides particular advantages over other known TiO₂ coatings. The use of nano-sized particles for the active ingredient and fillers additionally provides a coating superior oxidation resistance and heat resistance due to the large specific surface area, high surface activity, good adhesion and dispersion, anti-skinning/coalescent properties, uniform thickness distribution, fast curing, and good adhesion to metals, plastics, fabrics, glass, composites, ceramics, paper, inorganic paints, etc.

As previously described, known inorganic coatings such as sol gels that are comprised primarily of inorganic materials exhibit very limited working time before the coatings are cured, and must be rolled, brushed or sprayed. Due to this limitation in working time and application methods, known coatings are not suitable for continuous use in production plants. The present coating exhibits a pot life of up to 12 hours at room temperature, yet dries to the touch in about in 30 seconds once applied to the substrate, although complete drying typically takes longer. The present coating can be applied by spray, brush, roller, dipping, spin coating, capillary processes, flow coating, and various other methods. Thus, the present coating is particularly suitable for mass-production applications.

### EXAMPLES

Several exemplary coatings have been prepared in accordance with the formulations described below.

### Example 1

This formulation is to make a preferred embodiment of a primer coat for use on organic polymer substrates. The recommended applications of primer coat are spray coating techniques, rolling and brushing techniques, and dip coating techniques.

| | Chemical composition |
|---|---|
| Substance | of coating (% by weight) |
| Polyalkylphenylsiloxane | 44% |
| Xylene | 55.5% |
| Fumed silica | 0.5% |

The fumed silica is mixed with xylene and then stirred until the silica is substantially uniformly distributed. The polyalkylphenylsiloxane is added to the mixture and stirred homogenously. While the primer coat is utilized on substrates comprising organic polymer materials, its use is not restricted to application on organic polymer substrates, and may be used on any type of substrate if adhesion is a concern.

### Example 2

This formulation is recommended for spray coating technique, and rolling and brushing techniques.

| | Chemical composition |
|---|---|
| Substance | of coating (% by weight) |
| Polyalkylphenylsiloxane | 44% |
| Xylene | 50% |
| Fumed silica | 0.5% |
| NCPP | 5% |
| IABP | 0.5% |

The NCPP is mixed with xylene and stirred. While stirring the mixture, IABP, and then the fumed silica, are added until the powders are substantially uniformly dispersed. Then the polyalkylphenylsiloxane is added to the mixture and stirred until the powders are substantially homogenously dispersed. For spray applications, it may be necessary to readjust the solvent content to achieve the desired fluidity, which may in turn be dependent upon the spray parameters of the spray equipment utilized.

### Example 3

This formulation is recommended for dip coating technique, flow coating process, spin coat process and capillary coating process.

| | Chemical composition |
|---|---|
| Substance | of coating (% by weight) |
| Polyalkylphenylsiloxane | 44% |
| Xylene | 50% |
| Fumed silica | 0.1% |
| NCPP | 5.4% |
| IABP | 0.5% |

The NCPP is mixed with xylene and stirred. While stirring the mixture, IABP is added, followed by fumed silica. The mixture is stirred until it is properly mixed. Then the polyalkylphenylsiloxane is added to the mixture, which is stirred until a substantially homogenous mixture is obtained.

Technical Data

| | |
|---|---|
| Color: | Transparent white |
| Finish: | Semigloss |
| Percent Solids by volume: | 33 |
| Viscosity at 20° C.: | 10 cps |
| Specific gravity: | 0.96 |
| Flash point: | 85° F. |
| Pot life at room temperature: | 12 hours |
| Drying time at room temperature: | 30 seconds |
| Dry to touch: | 30 seconds |
| Dry to handle: | 15 minutes |
| Recoat: | 60 seconds |
| Recommended film thickness: | 1 to 5 mm |
| Shelf life: | 12 months |
| Solvent: | Xylene |

With respect to the photocatalytic coating solution, the most desirable coating properties are retained when the percentage by weight content of the NCCP and IABP individually does not exceed about 15% of the weight content of polyalkylphenylsiloxane in the formulation, and the percentage by weight of the densified hydrophilic fumed silica should not exceed about 5% of the weight content of polyalkylphenylsiloxane. Likewise, the percentage by weight content of xylene desirably should not exceed about 70% of the weight content of polyalkylphenylsiloxane. Excess xylene can undesirably increase the drying time. In addition, too much solvent could increase the fluidity of the mixture sufficiently so that temporarily, the mixture does not have thixotropic properties. In this situation, the advantages of the thixotropic composition are not available, making such a mixture undesirable for large industrial applications.

The coatings of the present invention can be applied to a wide variety of substrates, including both organic and inorganic substrates, using a wide variety of coating techniques and apparatus. The primer and photocatalytic coatings are exceptionally oxidation-resistant because of extremely low oxygen diffusivity, thereby providing oxidation protection to the underlying substrate. The photocatalytic coating dries to form a very thin coating that provides significant protection by promoting the growth of dense, stable oxide scale. It forms a hermetic nano composite coating through very simple coating techniques and processes.

As expected, the weight gain is much greater when the coatings are applied to rough surface substrates as opposed to highly polished substrates. However, as a general prerequisite for obtaining wet nano composite coating with good adhesion to substrates, a proper surface preparation is needed. All surfaces of the substrates should be clean, dry, and free of dirt, grease, oil, rust and other contaminants. Contaminated surfaces can be cleaned mechanically, if porous, or with a solvent, if non-porous. Glass can be cleaned with either water containing surfactant or a solvent. In latter case, the solvent should be applied with a clean oil free, lint free cloth. Residual solvent should be removed with a fresh, clean, dry cloth before it evaporates.

Inorganic substrates such as ceramic tiles, enamels, glass and a wide variety of metals do not require priming. By contrast, use of the primer of the present invention is recommended for organic substrates that cannot stand photocatalytic oxidation. Masking, such as with masking tapes, affords a simple and effective means of protecting critical areas from undesired contact with the coatings. Masking tapes should not be allowed to touch the clean faces of the joints, and should be removed immediately after the application and before the coating is dry.

The nano composite photocatalytic coating should be mixed or agitated by an agitation means that produces a smooth and homogeneous mixture, such as a power mixer. No straining with wire mesh is needed before use. As noted, the mixture can be applied by dip coating techniques, spray coating techniques, flow coating process, spin coating process, rolling and brushing techniques and capillary coating process. The preferred thickness will be from 1 to 5 μm (micron), although some methods will produce greater thicknesses, up to about 5 mils (0.005 mils). However, as the coating acts as a catalyst, greater thicknesses provide no advantage and only add weight and cost. The nano composite coating will dry to the touch at a room temperature at about 30 seconds, although complete drying by solvent evaporation will take longer, up to 12 hours. Some curing may occur as the solvent evaporates. The coating will further cure as it is exposed to ultra violet by way of photocatalytic reaction of leftover xylene, which is oxidizes to CO₂ and H₂O.

Dip coating technique is a process where substrate to be coated is immersed in the coating. The substrate is then withdrawn with a well-defined withdrawal speed under controlled temperature and atmospheric conditions. The thickness of the coating is determined by the withdrawal speed, the solid content and viscosity of the coating. The gelation of the coating depends on solvent evaporation. Therefore, it is important to have a controlled atmosphere where destabilization of the coating by solvent evaporation leads to a gelation process and the formation of a transparent film due to the nano size particles in the coating. However, by proper adjustment of the solvent content, a thixotropic coating will be produced on the substrate as it is withdrawn. If thicker coatings are desired, a multiple dipping process may be used, with each successive dip occurring after curing of the underlying layer.

Spray coating techniques are widely used in industry for organic coatings. The coating of the present invention can be applied by preferably using spraying equipment with HVLP (high volume, low pressure) nozzles. In the process of spraying, ultra fine droplets or atomizers are produced that lead to very homogeneous coatings on substrates. The coating material will hit on the substrates in the almost dried small particles in the nanometer range. The preparation of coating by spraying offers several advantages compared to dip coating: it is a faster process producing less waste; and it can be apply on large substrates and is suitable for in-line process in the plant. Furthermore, spraying can be controlled to provide various thicknesses in different areas, or no coating in preselected areas, if desired. The viscosity can be controlled to vary the thickness of the coating, and a plurality of coatings can also be applied to vary the coating thickness.

A flow coating process is a process wherein the coating is poured over the substrate. The thickness of the coating will depend on the angle of the inclination of the substrate with respect to the coating, the coating acting under the influence of gravity, the viscosity of the coating, the surrounding temperature and the solvent evaporation rate. The advantages of this process are that non-planar large substrates can be coated easily.

A spin coat process is a process wherein the substrate spins around an axis that is perpendicular to the area to be coated, thereby providing a rotational symmetry. The thickness of the coating will depend on the angular speed, the viscosity, the surrounding temperature and the solvent evaporation rate.

Rolling and brushing techniques are not state-of-the-art process. These processes require manual application and quite labor intensive. Such applications are recommended for large substrates that cannot be easily transported to a production plant environment. The thickness of the coating will depend on the skill of the workers, the speed of the workers, the type of applicator (such as roller and brush), the coating viscosity, the surrounding temperature and atmosphere, and the solvent evaporation rate. Although not state-of-the-art, brushing processes are still effective with the coating of the present invention due to the thixotropic nature of the coating.

Capillary coating process or laminar flow coating process is a combination of dip coating technique with the advantage that all of the coating can be used without much waste. A tubular dispenser containing the coating is moved under the substrate surface without physically contacting the surface. A spontaneous meniscus is created between the top of a cylinder and the substrate surface. Thus, a laminar deposition is accomplished whereby the coating is deposited homogeneously on the substrate. The thickness of the coating will depend on the deposition rate, the viscosity, the surrounding temperature and the solvent evaporation rate.

As with all industrial processes, certain precautions must be adhered to in applying the chemical composition to substrates. Since the present coating is organic-solvent based, proper safety precautions are needed during application of the coating. Normal precautions such as gloves and facemasks can be used. Adequate ventilation must be maintained all the time. Explosion proof lights and electrical equipment should be used, and workers should not wear sparking shoes or use sparking tools.

The nano coating film of the present invention facilitates photocatalytic oxidation as an effective approach to cope with wastewater treatment and exhaust gas since it enables the effective photocatalytic reaction of all types of organic substances, pathogens, and pollutants. Additionally, photocatalytic coating and ultraviolet light with wave length of 340 to 400 nm can be used for photocatalytic oxidation inside electrical appliances and other dark areas for deodorizing, cleaning, repelling micro organism and sterilizing of air. This application can further be used for air conditioners, dehumidifiers, refrigerators, deodorizer, heater, coolers, air purifiers, deodorizers, ventilation fans and germicidal equipment. The coatings can be applied on the surface concrete, gypsum, tiles, roofing, ceramic tiles, cultured stones, paints, ceilings, timbers, plastics, blinders, signage, furniture and grills. The coated substrates and products when exposed to sun light or ultra violet light will deodorize, clean, repel micro-organisms, and sterilize whatever organic compound stains might exist on its surfaces. The nano composite photocatalytic coating can also be used to make substrates bacteria proof. The photocatalytic action non-selectively kills viruses and bacteria having a chemical composition of protein and nucleic acid.

The coating of the present invention is particularly suited for use in HVACR applications in which water is present. The presence of water in these applications provides an environment which breed viruses and bacteria. Other chemicals may also be present. The present invention inhibits the growth of viruses and bacteria, as it is applied to surfaces, which are in contact with water and other chemicals. Thus, the coating of the present invention is applied to surfaces of HVACR equipment, which may come in contact with water, such as condensers, evaporators, chillers, and air handing systems. The invention may further be used in components such as air handling systems and air filtration systems, which have minimal contact with water, but do experience contaminants such as dust mites, mold spore and fungi. Frequently, this equipment is enclosed in spaces, which is not accessible to sunlight. Therefore, in order for the coating to effectively operate in these applications, it is necessary to provide a source of ultraviolet light. Preferably, the source should provide at least UVA, for which the coating acts as a catalyst, and, most preferably, also UVC, which individually affects bacteria and viruses. The UV light should be focused on the equipments coated with the present invention so that all fluids passing over the coated surfaces are simultaneously irradiated by the UV light sources.

While the invention has been described with reference to a preferred embodiment, it will be understood by those skilled in the art that various changes may be made and equivalents may be substituted for elements thereof without departing from the scope of the invention. In addition, many modifications may be made to adapt a particular situation or material to the teachings of the invention without departing from the essential scope thereof. Therefore, it is intended that the invention not be limited to the particular embodiment disclosed as the best mode contemplated for carrying out this invention, but that the invention will include all embodiments falling within the scope of the appended claims.

What is claimed is:

1. A nano-composite substantially inorganic photocatalytic coating, comprising in weight percent:
an effective amount of substantially inorganic binder up to about 50%;
fumed silica;
nano-sized photocatalytic powder;
an inorganic anti-bacterial powder of YX(P)₄)₃ that includes an antimicrobial metal, where Y is an element selected from Group IA and IIA of the Periodic table and X is an element selected from Group IIIA, IVA, VA and VIA of the periodic table; and
the balance an evaporable carrier liquid,
wherein the amount of fumed silica, nano-sized photocatalytic powder and inorganic anti-bacterial powder is provided in an amount sufficient to provide thixotropic properties to the coating composition.

2. The coating of claim 1 wherein the nano-sized photocatalytic powder is at least one element selected from the group consisting of titanium, zirconium, molybdenum, niobium, hafnium, tantalum and oxides thereof.

3. The coating of claim 1 wherein the inorganic binder is polyalkyphenylsiloxane.

4. The coating of claim 1 wherein the evaporable carrier liquid is selected from the group consisting of xylene and toluene and combinations thereof.

5. The coating of claim 1 wherein the evaporable carrier liquid is an alcohol.

6. The coating of claim 1 wherein the evaporable carrier liquid is selected from the group consisting of acetone and methyl ethyl ketone.

7. The coating of claim 1 wherein the antimicrobial metal is selected from the group consisting of silver, gold, platinum, palladium and rhodium and combinations thereof.

8. The coating of claim 1 wherein Y includes at least one of sodium, potassium and calcium.

9. The coating of claim 1 wherein X includes at least element selected from the group consisting of titanium, zirconium, yttrium, hafnium, tantalum, tungsten, and molybdenum.

10. The coating of claim 1 comprising, in weight percent:
an effective amount of polyalkyphenylsiloxane binder up to about 50%;
about 1% to about 10% of nanosized titanium dioxide photocatalytic powder;
0.5% to about 5% fumed silica;
about 1% to about 10% of a antibacterial nanopowder of NaX(PO₄)₃, the nanopowder of NaX(PO₄)₃ including at least 3% silver by weight, where X includes at least one element selected from the group consisting of titanium, zirconium, yttrium, hafnium, tantalum, tungsten, and molybdenum.
and the balance an evaporable solvent.

11. The coating of claim 10 wherein the evaporable carrier liquid is xylene.

12. The coating of claim 10 wherein the antibacterial nanopowder of NaX(PO₄)₃, includes, in weight percent, about 4.3% Na₂O, about 43.9% P₂O₅, about 0.02% NiO, about 3.8% Ag, about 1% HfO₂ and the balance ZrO₂ and incidental impurities.

13. The coating of claim 1 wherein the antibacterial nanopowder includes up to 99% by weight of a material selected from the group consisting of silver, oxides of silver and combinations thereof.

14. A HVACR system comprising:
at least one component having surfaces exposed to at least one of air and water, the surfaces including a coating of nano-composite substantially inorganic photocatalytic material, the nano-composite coating further comprising in weight percent, an effective amount of substantially inorganic binder up to about 50%, fumed silica, nano-sized photocatalytic powder, an inorganic anti-bacterial powder of YX(PO₄)₃ that includes an antimicrobial metal, where Y is an element selected from Group IA and IIA of the Periodic table and X is an element selected from Group IIIA, IVA and VA of the periodic table; and
at least one source of ultraviolet radiation irradiating the coated surface.

15. The HVACR system of claim 14 wherein the at least one component is selected from the group consisting of fan coils, air handling units, cassettes, water chillers, minisplits, evaporators, condensers and filters.

16. The HVACR system of claim 14 wherein the at least one source of ultraviolet radiation is UVA.

17. The HVACR system of claim 14 wherein the at least one source of ultraviolet radiation includes UVA and UVC.

18. The HVACR system of claim 14 wherein the at least one component of the HVACR system exposed to at least one of air and water comprises a surface coated with, in weight percent after evaporation of an evaporable carrier liquid, up to about 3.7% fumed silica, up to about 11% of an antibacterial nanosized powder of NaX(PO₄)₃, the nanopowder of NaX(PO₄)₃ including at least 3% silver by weight, where X includes at least one element selected from the group consisting of titanium, zirconium, yttrium, hafnium, tantalum, tungsten, and molybdenum, up to about 11% nanosized titanium dioxide photocatalytic powder and the balance binder.

19. The HVACR system of claim 14 wherein the at least one component of the HVACR system exposed to at least one of air and water comprises a surface coated with, in weight percent after evaporation of an evaporable carrier liquid, an effective amount of polyalkyphenylsiloxane binder up to about 65%, about 7% to about 14% fumed silica, about 13% to about 28% of an antibacterial nanosized powder of NaX(PO₄)₃, the nanopowder of NaX(PO₄)₃ including at least 3% silver by weight, where X includes at least one element selected from the group consisting of titanium, zirconium, yttrium, hafnium, tantalum, tungsten, and molybdenum and the balance nanosized titanium dioxide photocatalytic powder.

20. The HVACR system of claim 14 further including a primer coat overlying the surfaces of the component and underlying the nano-composite coating.

21. The HVACR system of claim 20 wherein the primer coat comprises, after evaporation of an evaporable carrier liquid, polyalkylphenylsiloxane and silica.

22. The HVACR system of claim 21 wherein the primer coat comprises, after evaporation of an evaporable carrier liquid, about 0.01% fumed silica and the balance polyalkylphenylsiloxane.

23. The HVACR system of claim 14 wherein the source of ultraviolet radiation is a powered source that provides at least UVA radiation.

24. The HVACR system of claim 14 wherein the source of ultraviolet radiation is a powered source that provides at least UVC radiation.

25. The HVACR system of claim 14 wherein the nano-composite coating has a thickness of up to 0.005 inches.

26. The HVACR system of claim 25 wherein the coating has a thickness of from about 1 micron to about 5 microns.

27. A method for applying a nano-composite substantially inorganic photocatalytic coating to a surface comprising the steps of:
providing an effective amount of substantially inorganic binder up to about 50 w/o;
providing between about 0.5-5 w/o fumed silica;
providing about 1 w/o to about 10 w/o nano-sized photocatalytic powder;
providing about 1 w/o to about 10 w/o inorganic anti-bacterial powder of YX(PO₄)₃ and an antimicrobial metal, where Y is an element selected from Group IA and IIA of the periodic table and X is an element selected from Group IIIA, IVA, VA and VIA of the periodic table;
providing an evaporable carrier liquid as a balance of the mixture;
adding the nano-sized photocatalytic powder to the carrier liquid and mixing to substantially uniformly distribute the powder in the carrier liquid;
adding the inorganic anti-bacterial powder to the carrier liquid and mixing to substantially uniformly distribute the inorganic power in the carrier liquid;
then adding the fumed silica to the mixture and mixing to substantially uniformly distribute the fumed silica in the mixture; then
adding the inorganic binder to the evaporable carrier and mixing to substantially uniformly distribute the binder in the carrier;
wherein the fumed silica, nano-sized photocatalytic powder and inorganic anti-bacterial powder in the evaporable carrier provide thixotropic properties to the coating mixture; then
adjusting the quantity of evaporable carrier liquid to provide a mixture viscosity suitable for application of the thixotropic mixture to the surface;
applying the thixotropic mixture to the surface; and
manipulating the thixotropic mixture on the surface as required to coat substantially the entire surface.

28. The method of claim 27 further including the step of cleaning the surface to remove contaminants prior to applying the nano-composite coating.

29. The method of claim 27 further including the step of applying a primer coat after the step of cleaning and prior to the step of applying the nano-composite coating.

30. The method of claim 29 wherein the step of applying the primer coat includes applying a primer coat comprising polyalkylphenylsiloxane and fumed silica and the balance xylene.

31. The method of claim 30 wherein the step of applying the primer coat includes applying a primer coat comprising about 44% polyalkylphenylsiloxane, about 0.5% fumed silica and the balance xylene.

32. The method of claim 27 wherein the step of providing the inorganic anti-microbial powder includes providing an antimicrobial powder comprising, in weight percent, about 4.3% Na₂O, about 43.9% P₂O₅, about 0.02% NiO, about 3.8% Ag, about 1% HfO₂ and the balance ZrO₂ and incidental impurities.

33. The method of claim 27 wherein the step of applying the thixotropic mixture to the surface is selected from the group of application methods consisting of spraying, dipping, rolling, brushing, spin coating, flow coating and capillary coating.

34. The method of claim 33 wherein the step of applying a thixotropic mixture to the surface includes providing a coating of the thixotropic mixture to a thickness of up to about 0.005 inches.

35. The method of claim 34 wherein the step of applying a thixotropic mixture to the surface includes providing a coating of the thixotropic mixture to a thickness of about 0.001-0.005 microns.

36. The method of claim 27 wherein the step of providing a nano-sized photocatalytic powder includes providing nanosized titanium dioxide powder.

37. The method of claim 27 wherien the step of providing an inorganic binder includes providing polyalkyphenylsiloxane.
